(19) United States
(12) Patent Application Publication
(10) Pub. No.: US 2004/0222520 A1
(43) Pub. Date: Nov. 11, 2004

(54) INTEGRATED CIRCUIT PACKAGE WITH FLAT METAL BUMP AND MANUFACTURING METHOD THEREFOR

(76) Inventor: Yonggang Jin, Singapore (SG)

Correspondence Address: THE LAW OFFICES OF MIKIO ISHIMARU, 1110 SUNNYVALE-SARATOGA ROAD, SUITE A1, SUNNYVALE, CA, 94087, US

(21) Appl. No.: 10/251,512

(22) Filed: Sep. 19, 2002

(51) Int. Cl. H01L 21/44; H01L 21/48; H01L 21/50; H01L 29/40

(52) U.S. Cl. 257/737; 438/614

(57) ABSTRACT

A flat gold bump, and manufacturing method therefor, is provided. An under bump metallurgy is formed on the contact pad in and around the opening. A bump pad is formed over the under bump metallurgy and a flat gold bump is formed on and over the bump pad.

### BACKGROUND

1. Technical Field

The present invention relates generally to the fabrication of semiconductor integrated circuit packages, and more specifically to packages with metal bumps for making electrical connections.

2. Background Art

Electronic products have become an aspect of every day life from televisions to cell phones to wristwatches. The hearts of these electronic products are integrated circuits, which continue to be made smaller and more reliable while increasing performance and speed.

An integrated circuit is typically packaged in a tiny box-type structure usually on the order of a few millimeters per side. The integrated circuit package generally has cylindrical terminals formed through a passivation layer of the integrated circuit near its edges for directly bonding the integrated circuit package to a foil-type lead frame that is usually less than 0.5 mm in thickness.

The bonding technique is referred to as tape automated bonding or TAB. In the TAB process a lead tape is first prepared by etching electrical leads into it at positions corresponding to the locations of the cylindrical terminals on the integrated circuit package. The lead tape is then fed into an inner lead bonder, which is an apparatus equipped with a thermode (a heated instrument that presses the integrated circuit package and the tape together). The inner ends of the electrical leads are bonded to the cylindrical terminals on the integrated circuit package by compressing them together in the heated thermode in a single operation.

The integrated circuit package and the bonded leads can then be excised out of the tape for connection to a circuit board, which goes into the electronic products.

The cylindrical terminals on the integrated circuit are often called “gold bumps” because they are gold-plated and look like bumps protruding from the integrated circuit package. This structure is required because aluminum metallization is typically used for wiring inside integrated circuits so input/output contact pads under the passivation layer are typically aluminum or aluminum alloy.

Aluminum and aluminum alloys are highly susceptible to corrosion if left exposed to the environment and, as a result, one or two protective passivation layers of silicon oxide, silicon nitride or polyimide are applied. Then an opening is formed by plasma or reactive ion etching in the passivation layers to expose the input/output contact pad. The thin film deposition is performed by evaporation or sputtering. The thin film layers deposited are called “under bump metallurgy” (UBM). UBM plays critical roles: as an adhesion layer between the aluminum metallization and the gold bumps; and as a common ground for the subsequent electroplating of the gold bump. Before plating, a photoresist layer is coated and developed to define the opening for bumps. The photoresist opening must have some overlap on both side of passivation opening to protect the aluminum input/output contact pad during UBM etching after plating because acid will be applied during etching. The overlap is from 6 um to 10 um depending on the exposure tools and process control. During plating, the plating rate is same at everywhere, so the final surface of gold bump is not flat because of the thickness of the passivation layers. At center area of the gold bump, the thickness is always lower, like the center of a ring. If the thickness of the passivation layers is less than 1 um, there is no any problem. But more products now require passivation layers, which are more than 1 um thick so the current technology is limited.

A solution to this problem has been long sought but prior developments have not taught or suggested any solutions and, thus, a solution to this problem has long eluded those skilled in the art.

### SUMMARY OF THE INVENTION

The present invention provides an integrated circuit package, and manufacturing method therefor. A contact pad and a passivation layer are formed on the integrated circuit. An opening is formed in the passivation layer exposing the contact pad. An under bump metallurgy is formed over the contact pad and the passivation layer. A bump pad is formed over the under bump metallurgy, and a bump is formed on and over the bump pad. The bump has a top flat surface. The TAB using the bump technology of the present invention provides bonds that hold and have a flat surface and low resistance even with reductions in the size of the technology.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 (PRIOR ART) is a cross-sectional view of prior art integrated circuit package;

FIG. 2 is a close up view of an integrated circuit package with a contact pad in an intermediate stage of manufacture according to the present invention;

FIG. 3 is the structure of FIG. 2 after deposition of an under bump metallurgy;

FIG. 4 is the structure of FIG. 3 after plating of a bump pad;

FIG. 5 is the structure of FIG. 4 after plating of a bump;

FIG. 6 is the completed integrated circuit package with a bump in accordance with the present invention; and

FIG. 7 is a flowchart of a method for manufacturing an integrated circuit package with a gold bump in accordance with the present invention.

### DETAILED DESCRIPTION OF THE INVENTION

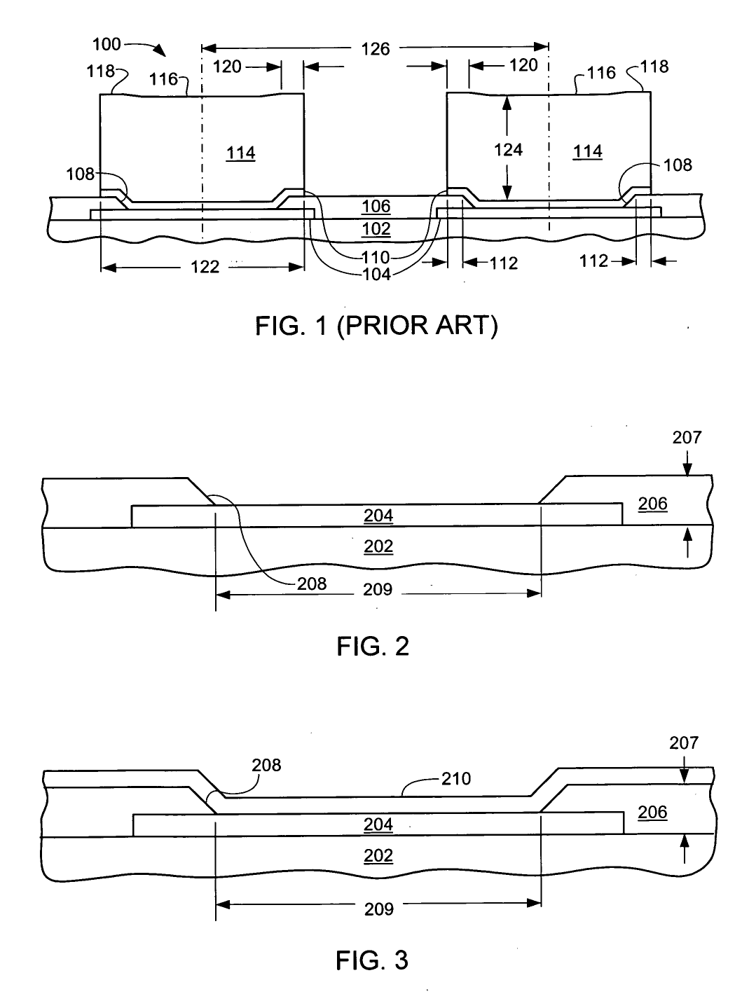

Referring now to FIG. 1 (PRIOR ART), therein is shown a cross-sectional view of a integrated circuit package 100 in the prior art. The integrated circuit package 100 includes an integrated circuit 102 having input/output contact pads 104 under a passivation layer 106.

The term “horizontal” as used in herein is defined as a plane parallel to the conventional plane or under surface of the integrated circuit package, such as the integrated circuit package 100, regardless of its orientation. The term “vertical” refers to a direction perpendicular to the horizontal as just defined. Terms, such as “on”, “above”, “below”, “side”, “higher”, “lower”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

The passivation layer 106 has openings 108 provided therein which expose the input/output contact pads 104. Under bump metallurgies (UBMs) 110 line the openings 108 and extend distances 112 beyond the edges of the openings 108. Where the openings 108 are rectangular, the UBMs 110 are rectangular.

Bumps 114 are deposited on the UBMs 110 by a plating process. The bumps 114 for the UMBs 110 will be of substantially rectangular block configurations; e.g., blocks with rounded corners and flat tops. Different configurations of the UMBs 110 are possible including cylindrical and cubical.

It has been unexpectedly discovered, while investigating the problems of poor bonding and poor electrical connection using the bumps 114, that the bumps 114 do not have flat top surfaces which match with the flat surface of the lead tape (not shown) to which the bumps 114 are bonded.

In order to protect the input/output contact pads 104 from corrosion, it is necessary that the UBM 110 must extend the distances 112 beyond the openings 108. It has been discovered that the thicknesses of the passivation layer 106 in the distances 112 causes the top surfaces of the bumps 114 to have depressions 116 surrounded by rectangular ring structures 118 having ring thicknesses 120.

In some embodiments, the ring thicknesses 120 are about 5 \check{s}m to about 10 sm thick in a horizontal direction and about 1 \check{s}m in a vertical direction. Since the thickness of the passivation layer 106 is about 1 \check{s}m, the uniform bump plating causes the depression 116 to be around 1 \check{s}m deep. The depression 116 is extremely small, but it is believed that the rectangular ring structures 118 are sufficiently deep and large enough to entrap air in the depressions 116 between the bumps 114 the flat tape during TAB and sometimes prevent bonding and/or sometimes affect the electrical properties of the bond.

The bumps 114 of the prior art have widths 122, heights 124 and are spaced apart a center-to-center distance 126.

Referring now to FIG. 2, therein is shown a close up view of an integrated circuit package 200 in an intermediate stage of manufacture according to the present invention. The integrated circuit package 200 includes an integrated circuit 202 having an input/output contact pad 204 under a passivation layer 206. In one embodiment, the input/output contact pad 204 is of aluminum or an aluminum alloy under the passivation layer 206 of a dielectric material.

The passivation layer 206 is deposited to a thickness 207 and has an opening 208 provided therein which exposes the input/output contact pad 204 to define a contact area 209. Where the opening 208 is rectangular, the contact area 209 will have a contact width and contact length as dimensions. Where the opening 208 is circular or square, the contact area 209 will have a diameter or a width as dimensions.

Referring now to FIG. 3, therein is shown the structure of FIG. 2 after deposition of an under bump metallurgy (UBM) 210. In one embodiment of the present invention, the UMB 210 includes a first layer of titanium-tungsten alloy or chrome and a second layer of gold, which are successively deposited on the contact area 209 and the passivation layer 206 by sputter deposition.

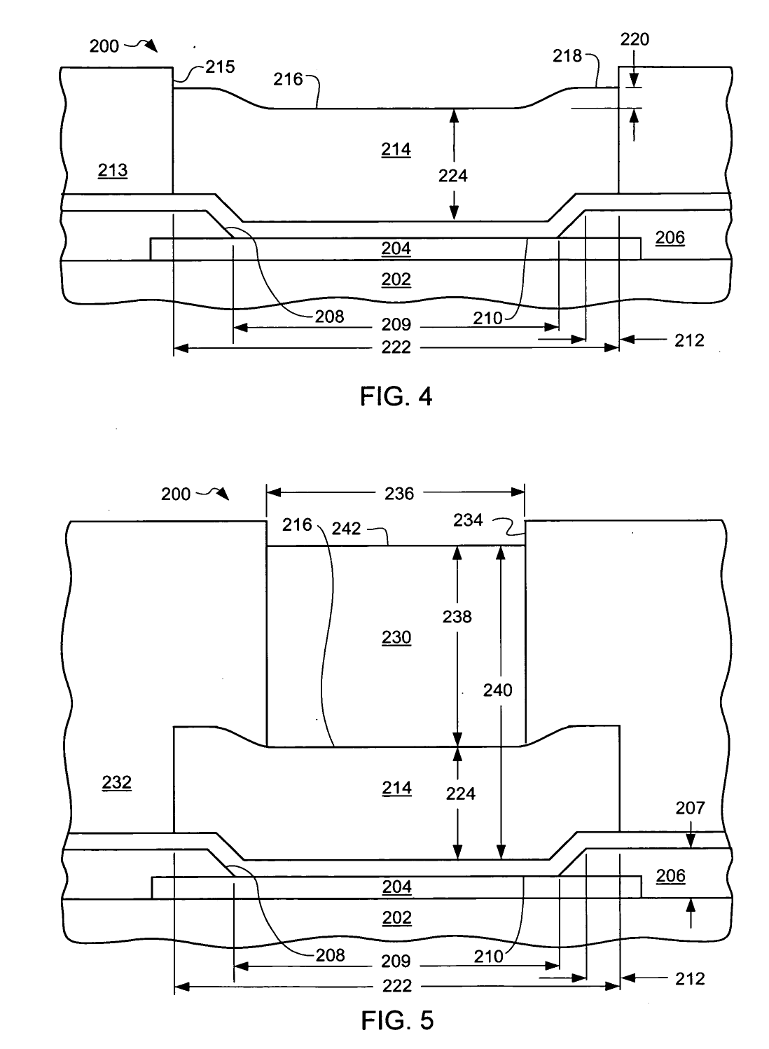

Referring now to FIG. 4, therein is shown the structure of FIG. 3 after plating of a bump pad 214. The bump pad 214 is formed in a number of steps.

A photoresist 213 is deposited, patterned, and processed on the under bump metallurgy to form an opening 215. The opening 215 will extend beyond the perimeter of the opening 208 by a distance 212 to provide corrosion protection for the input/output contact pad 204 when applying the under bump metalurgy etching later. Where the opening 208 is rectangular, the opening 215 is rectangular and has an outside dimension 222. The bump pad 214 is formed on the UMB 210 by plating in the opening 215 using the UMB 210 as a common ground.

The bump pad 214 can be of a conductive material such as gold, nickel, etc. It will be noted that the thickness of the passivation layer 206 in the distance 212 causes the top surface of the bump pad 214 to have an depression 216 surrounded by a rectangular ring structure 218 having a ring thicknesses 220.

The bump pad 214 will have a cross-sectional area with a dimension 222 and a height 224 above the UBM 210. The height 224 will be less than the height 124 of FIG. 1 (PRIOR ART).

Referring now to FIG. 5, therein is shown the structure of FIG. 4 after plating of a bump 230.

In one embodiment, a photoresist 232 has been deposited over the photoresist 213 of FIG. 4 and the bump pad 214. The photoresist 232 has been patterned and processed to form an opening 234 around the depression 216 of the bump pad 214.

The bump 230 can be of a conductive material such as gold, which can deposited by a number of different methods including plating. The bump pad 214 and the bump 230 can be of different materials to conserve cost or the same materials to improve electrical performance. In one embodiment, the bump 230 is gold deposited by plating to be compatible with the tape automated bonding (TAB) process, which requires the integrated circuit 200 to bond to a copper, gold, tin plated copper, or a copper/plastic laminated tape.

The bump 230 has been plated into the opening 234 to have a cross-sectional area with a dimension 236 which is less than a dimension 209 and a height 238 over the UBM 210 so as to have an overall height of 240. In one embodiment, the overall height 240 is same to the height 124 of FIG. 1 and greater than the height 224.

Since the bottom of the depression 216 is flat within 0.5 um, the top surface 242 of the bump 230 will be flat within 0.5 um regardless of the thickness 207 of the passivation layer 206. As used herein, the term “flat” will mean a degree of flatness within 0.5 um. This means that the top surface 242 of the bump 230 will not have a depression so proper bonding will always occur and the electrical properties of the bond will be uniform despite size reductions in the technology and in the bump 230.

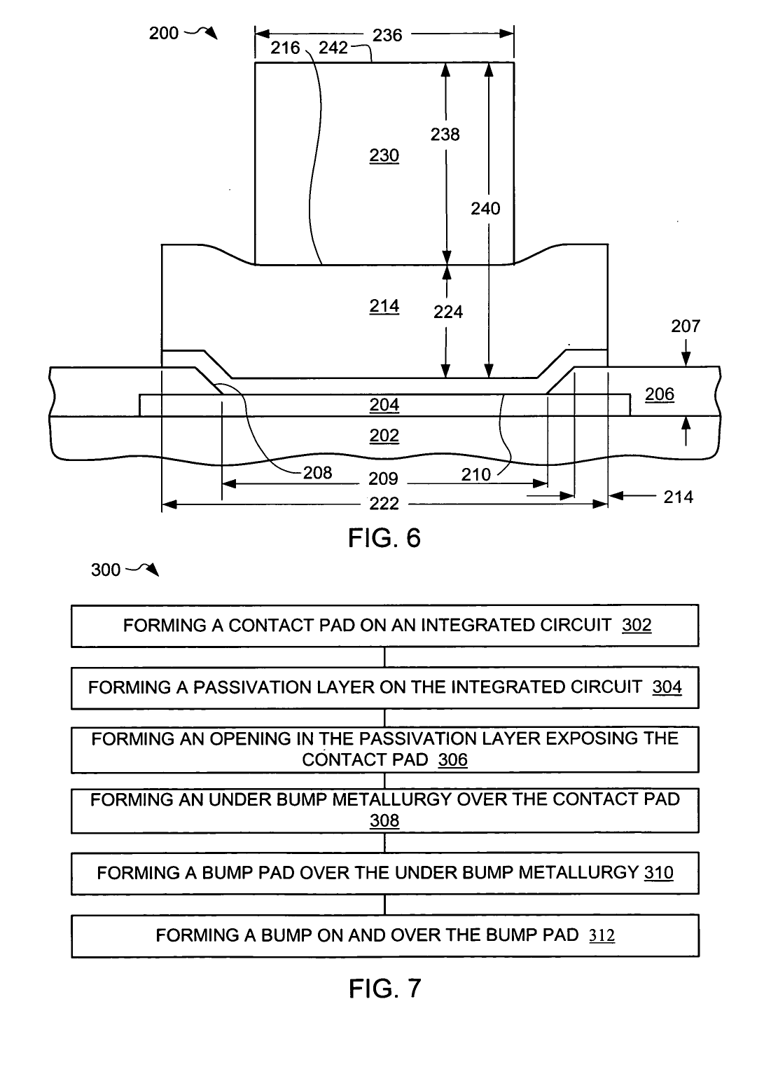

Referring now to FIG. 6, therein is shown the completed integrated circuit package 200 with the bump 230 in accordance with the present invention. The photoresist 232 has been removed and UBM 210 has been etched to the size of the bump pad 214.

Referring now to FIG. 7 therein is shown a flowchart of a method 300 for manufacturing an integrated circuit package with a bump in accordance with the present invention. The method 300 includes: a step 302 of forming a contact pad on an integrated circuit; a step 304 of forming a passivation layer on the integrated circuit; a step 306 of forming an opening in the passivation layer exposing the contact pad; a step 308 of forming an under bump metallurgy over the contact pad; a step 310 forming a bump pad over the under bump metallurgy; and a step 312 of forming a bump on and over the bump pad.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the spirit and scope of the included claims. All matters hither-to-fore set forth or shown in the accompanying drawings are to be interpreted in an illustrative and non-limiting sense.

The invention claimed is:

1. A method of manufacturing an integrated circuit package comprising:
forming a contact pad under a passivation layer on an integrated circuit;
forming an opening in the passivation layer exposing the contact pad;
forming an under bump metallurgy over the contact pad and the passivation layer;
forming a bump pad over the under bump metallurgy; and
forming a bump on and over the bump pad, the bump having a top flat surface.

2. The method as claimed in claim 1 wherein forming the bump pad and forming the bump use different materials.

3. The method as claimed in claim 1 wherein:
forming the bump pad forms the bump pad with a first cross-sectional area; and
forming the bump forms the bump having a second cross-sectional area wherein the first cross-sectional area is larger than the second cross-sectional area.

4. The method as claimed in claim 1 wherein forming the bump forms the top flat surface with the same flatness as the contact pad.

5. The method as claimed in claim 1 wherein forming the under bump metallurgy includes the under bump metallurgy contacting the contact pad over a contact area and forming the bump forms a bump having a smaller cross-sectional area than the contact area.

6. A method of manufacturing an integrated circuit package comprising:
forming an input/output contact pad on an integrated circuit;
forming a passivation layer on the integrated circuit;
forming an opening in the passivation layer exposing the contact pad;
forming an under bump metallurgy over the contact pad and the passivation layer;
forming a bump pad over the under bump metallurgy using a first photoresist; and
forming a gold bump on and over the bump pad using a second photoresist, the gold bump having a flat top surface.

7. The method as claimed in claim 6 wherein forming the bump pad uses a material selected from a group consisting of gold, nickel, and a combination thereof.

8. The method as claimed in claim 6 wherein:
forming the bump pad forms the bump pad with a first dimension; and
forming the gold bump forms the gold bump having a second dimension wherein the first dimension is larger than the second dimension.

9. The method as claimed in claim 6 wherein forming the gold bump forms the top flat surface with the same flatness as the contact pad and flat within 0.5 um.

10. The method as claimed in claim 6 wherein:
forming the bump pad forms the bump pad with a depression having a first dimension on the top thereof; and
forming the gold bump forms the gold bump with a second dimension wherein the second dimension is smaller than the first dimension.

11. An integrated circuit package comprising:
an integrated circuit;
a contact pad on the integrated circuit;
a passivation layer on the integrated circuit having an opening provided therein exposing the contact pad;
an under bump metallurgy over the contact pad and the passivation layer;
a bump pad over the under bump metallurgy; and
a bump with a top flat surface on and over the bump pad.

12. The integrated circuit package as claimed in claim 11 wherein the bump pad and the bump are different materials.

13. The integrated circuit package as claimed in claim 111 wherein:
the bump pad has a first cross-sectional area; and
the bump has a second cross-sectional area wherein the first cross-sectional area is larger than the second cross-sectional area.

14. The integrated circuit package as claimed in claim 11 wherein the top flat surface has the same flatness as the contact pad.

15. The integrated circuit package as claimed in claim 11 wherein the under bump metallurgy contacts the contact pad over a contact area and the bump has a smaller cross-sectional area than the contact area.

16. An integrated circuit package comprising:
an integrated circuit;
an input/output contact pad on the integrated circuit;
a passivation layer on the integrated circuit having an opening provided therein exposing the contact pad;
an under bump metallurgy over the contact pad and the passivation layer;
a bump pad over the under bump metallurgy; and
a gold bump on and over the bump pad, the gold bump having a flat top surface.

17. The flat gold bump as claimed in claim 16 wherein the bump pad is a material selected from a group consisting of gold, nickel, and a combination thereof.

18. The flat gold bump as claimed in claim 16 wherein:
the bump pad has a first dimension; and
the gold bump has a second dimension wherein the first dimension is larger than the second dimension.

19. The flat gold bump as claimed in claim 16 wherein the top flat surface has the same flatness as the contact pad and is flat within 0.5 um.

20. The flat gold bump as claimed in claim 16 wherein:
the bump pad has a depression having a first dimension on the top thereof; and
the gold bump has a second dimension wherein the second dimension is smaller than the first dimension.
